(19) United States
(12) Patent Application Publication
(10) Pub. No.: US 2003/0236004 A1
(43) Pub. Date: Dec. 25, 2003

(54) Dechucking with N2/O2 plasma

(75) Inventors: Shing-Li Sung, HsinChu (TW); Chih-Pang Chen, Yong He City (TW); Huei-Chen Yu, Changhua (TW)

Correspondence Address: PATENT COUNSEL, APPLIED MATERIALS, INC., Legal Affairs Department, P.O. BOX 450A, Santa Clara, CA, 95052, US

(73) Assignee: Applied Materials, Inc.

(21) Appl. No.: 10/179,005

(22) Filed: Jun. 24, 2002

(51) Int. Cl. H01L 21/00

(52) U.S. Cl. 438/795

(57) ABSTRACT

A method for dechucking a wafer placed on an electrostatic chuck after plasma processing of the wafer comprises the steps of providing a flow of nitrogen and oxygen, maintaining a N₂/O₂ plasma in the chamber; and changing the electric potential of a chuck electrode to a dechucking electric potential before turning off the plasma.

The present application relates to semiconductor processing technologies, and particularly to a method of dechucking a wafer processed in a plasma reactor.

### BACKGROUND OF THE INVENTION

In semiconductor fabrication, a workpiece or wafer processed in a plasma reactor must be securely held in a fixed position within a vacuum chamber of the plasma reactor. Various techniques have been used to hold the workpiece in a desired position within the chamber. Early techniques involved mechanically clamping the topside of the wafer. Mechanical clamping produced problems of non-uniformity and particle inconsistencies at the edge of the workpiece, and is being replaced by the more recent technology of electrostatic clamping. The electrostatic clamping techniques make use of the electrostatic attraction between objects holding opposite charges or having different electrical potentials, such as the force of attraction between charged plates of a capacitor. In its simplest form, the apparatus for electrostatic clamping, commonly called an electrostatic chuck or e-chuck, is in effect a parallel plate capacitor having a chuck electrode acting as one conductive plate, a coating on the electrode acting as an insulating layer, and the wafer acting as another conductive plate.

A method of providing the electrostatic clamping force is by connecting the chuck electrode to a DC voltage source and using a gas plasma within the chamber as a conductor to complete the electrical circuit. With this method, the wafer is not charged until the plasma has been generated in the chamber, and the combination of the DC voltage and the plasma results in clamping or chucking the wafer on the chuck electrode. After the wafer is electrostatically chucked, the desired process is carried out in the chamber, following which the wafer needs to be unclamped or dechucked before being removed from the chamber. Wafer dechucking is typically achieved by grounding the chuck electrode and discharging the wafer. Wafer discharging can be done by running a plasma of a non-process gas in the chamber.

Argon plasma has been most commonly used for dechucking because of its low chemical impact on the processed wafer. But dechucking with Argon plasma is problematic for some etching processes such as the ones involving polymer deposition or sidewall passivation. For example, in etching vias or holes in a semiconductor device, polymer deposition is widely used to achieve anisotropy and selectivity. Argon plasma tends to harden the polymer residue left on the etched feature surfaces, making the polymer residue much harder to remove with post-etch cleaning procedures, such as photoresist ashing and solvent clean. The polymer residue left in the holes or vias after the post-etch cleaning procedures may cause deviation in device parameters, and even open circuits in the semiconductor device.

### SUMMARY OF THE INVENTION

The present invention overcomes the aforementioned shortcomings of the conventional method of using Argon plasma for dechucking by using instead N₂/O₂ plasma in a dechucking procedure. The N₂/O₂ plasma tends to soften instead of harden the polymer residues on the wafer, and makes it easier instead of harder to remove the polymer residues from the wafer with post-etch cleaning procedures.

In one embodiment of the present invention, a method for separating the wafer from the electrostatic chuck comprises the steps of: providing a flow of nitrogen and oxygen; maintaining a N₂/O₂ plasma while bringing the electric potential of the chuck electrode to a dechucking level; and separating the wafer from the electrostatic chuck.

### BRIEF DESCRIPTION OF THE DRAWINGS

Additional objects and features of the invention will be more readily apparent from the following detailed description and appended claims when taken in conjunction with the drawings, in which:

FIG. 1 is a block diagram of an electrostatic chuck incorporated in a plasma reactor according to one embodiment of the present invention;

FIG. 2 is a flow chart illustrating a dechucking method according to one embodiment of the present invention.

FIG. 3 includes several scanning electron micrographs (SEM) taken from two wafers showing the effect of N₂/O₂ dechucking plasma on polymer removal.

### DESCRIPTION OF ILLUSTRATIVE EMBODIMENTS

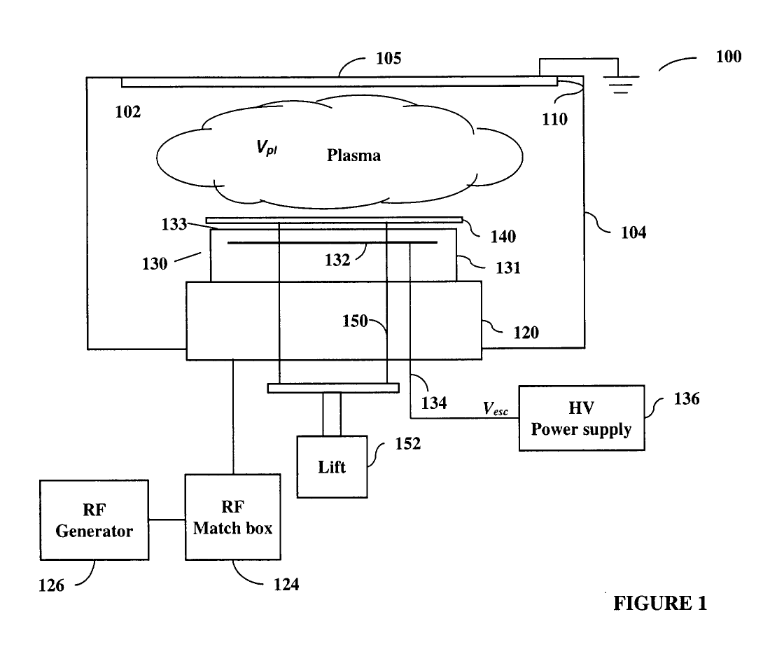

The dechucking method of the present invention can be used in combination with most e-chucks. FIG. 1 shows an example of such an e-chuck 130 disposed in a vacuum chamber 102 of a plasma reactor 100.

In one embodiment of the present invention, the chamber 102 includes a wall 104, a ceiling 105, and a disc-shaped top electrode 110 just below the ceiling 105. The chamber wall 104 is usually made of aluminum with anodized aluminum coating on the surface facing the inside of the chamber 102, and is typically grounded. The chamber 102 further includes a pedestal or bottom electrode 120 for supporting a workpiece or wafer in the chamber 102. Usually the top electrode 110 is grounded, and the pedestal or bottom electrode 120 is connected to a radio frequency (RF) power source 126 through an impedance match network 124. The chamber 102 may optionally be surrounded by plural magnets (not shown) to provide a slowly rotating magnetic field in the chamber 102.

FIG. 1 only shows one configuration of the many plasma reactors that can be used to practice the present invention. For example, the reactor 100 may include other power sources in addition to or in place of the RF power source 126, and power can be coupled into the chamber 102 to strike and maintain a plasma therein through differently configured coupling hardware as is known in the art, without affecting the application of the present invention.

The e-chuck 130 is placed on the pedestal 120 and includes a disk shaped dielectric or ceramic plate 131 with planar top face 133 and a metal chuck electrode 132 placed therein. In one embodiment of the present invention, the thickness of the plate 131 is about 4-10 mm. An insulated wire 134 connects the chuck electrode 132 through a bore (not shown) in the pedestal 120 to a DC high voltage (HV) supply 136. In one embodiment, the plate 131, the chuck electrode 132 and the pedestal 120 have vertical holes to allow a few lift pins 150 to raise or lower a workpiece or wafer 140 on the chuck 130, using a conventional lift mechanism 152. As in other types of wafer clamping or chucking devices, a cooling gas to control wafer temperature is typically supplied to the backside of the wafer by a cooling gas distribution system (not shown). Thus, the top surface 133 of the e-chuck 130 typically has channels or grooves (not shown) to allow circulation of a cooling gas. In one embodiment of the present invention, the cooling gas is Helium.

In the typical operation of the plasma reactor 100, a robot arm (not shown) moves a workpiece or wafer 140 into the chamber 102 through a slit valve (not shown) on the wall 104 of the chamber 102. The robot places the wafer on the tips of lift pins 150, which at this time are elevated by the lift mechanism 152 so as to protrude a couple of centimeters above the top of the e-chuck 130. The lift mechanism 152 then lowers the lift pins 150 so that the wafer 140 is gently placed on the e-chuck 130. The lift pins are then retracted below the top surface. In one embodiment of the present invention, the lift pins are made of a nonconductive material such as ceramic.

Shortly after the wafer 102 is lowered onto the e-chuck 130, a gas is introduced into the chamber 102. When the gas pressure in the chamber 102 has stabilized at an appropriate level, the RF source power 126 is turned on, using a pre-selected set of conditions that strikes a chucking plasma in the chamber 102 at the gas pressure. In the meantime, the impedance match network 124 is tuned to couple maximum power to the plasma. Quickly afterwards, the DC voltage supply 136 to the e-chuck is turned on so that a DC voltage, or chucking voltage, is applied to the chuck electrode 132.

With the chucking plasma running, the wafer is grounded or nearly grounded because the plasma provides a conductive path from the wafer to the grounded top electrode 110 and/or the chamber wall 104. Thus a voltage that is close to the chucking voltage appears between the wafer 140 and the chuck electrode 132. This voltage causes opposite charges to accumulate on the facing surfaces of the wafer and chuck electrode 132. The amount of charge is proportional to the product of the voltage and the capacitance between the wafer and the chuck electrode 132. The opposite polarity charges on the wafer and the chuck electrode produce an electrostatic attraction force that presses the wafer against the upper face of the chuck. The chucking voltage is set to a value high enough to produce an electrostatic force between the wafer and the chuck that prevents wafer movement during subsequent process steps. Generally, the chucking voltage is on the order of a few hundred to a few thousand volts (positive or negative). In one embodiment of the present invention, the chucking voltage is in the range of 300-800 volts. The wafer thus retained securely on the chuck is said to be “chucked”.

After the wafer is chucked, the backside cooling gas is turned on because the electrostatic force is now sufficient to overcome the backside pressure on the wafer exerted by the cooling gas. The plasma for chucking can be part of one or more fabrication process steps for processing the wafer. In one embodiment of the present invention, chucking is performed during a descum step preceding a main etch step to etch holes or vias in a dielectric layer on the wafer. As an example, the descum step is run with a gas mixture including mostly Argon and a small amount of one or more of the following gases: C₄F₆, O₂, CHF₃, CO. The pressure in the chamber is maintained at 20-60 mT, the RF power at 1000-1800 W, the magnetic field at 0-80 Gauss, and the temperature of the wafer at 30° C.

Next, a transition to the desired process gas for a processing step is initiated. During the transition, the RF bias power is adjusted and the impedance match network is tuned to couple maximum power to the plasma under the new conditions. At this point, the processing step has begun and it is run for the desired length of time. As an example, the processing step includes a main etch step for etching dielectric holes or vias and is run with a processing plasma of a gas mixture including Argon and one or more of the following gases: C₄F₆, O₂, CHF₃, CO. The pressure in the chamber is maintained at 20-60 mT, the RF power at 1000-2000 W, the magnetic field at 0-80 Gauss, and the temperature of the wafer at 30° C. Optional processing steps such as an over-etch step may be performed at the conclusion of the main etch step.

After completion of the processing steps, the wafer needs to be removed from the chamber 102. However, before the lift pins 150 can raise the wafer, the wafer must be dechucked to remove the electrostatic force retaining the wafer on the chuck 130.

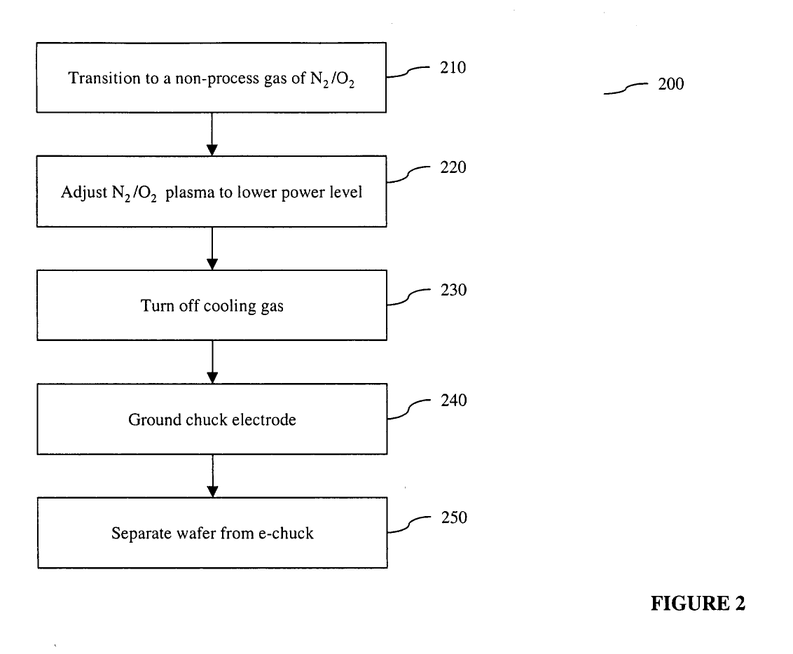

FIG. 2 illustrates a method 200 for dechucking the wafer 140. First, there is a transition to a non-process gas (step 210). In one embodiment of the present invention, the non-process gas is a mixture of Nitrogen (N₂) and Oxygen (O₂). The transition is made by stopping the flow of the process gas and providing a flow of N₂/O₂ gases. The ratio of the flow rates of the N₂ and O₂ gases or the percentage of each gas in the gas mixture varies according to different applications. In general, a higher N₂ to O₂ flow ratio or higher N₂ percentage in the gas mixture is used when there are more metallic polymers left on the feature surfaces. The flow rates of the N₂ and O₂ gases can each be about 5 standard cubic centimeters per minute (sccm) to about 300 sccm. In one embodiment of the present invention, the flow rates of the N₂ and O₂ gases are each about 50 sccm.

In one embodiment of the present invention, the transition 210 is made when the plasma is still running, but the RF power is adjusted at the meantime to a much lower level and the impedance match network 124 is tuned accordingly (step 220). In an alternative embodiment, after the processing steps, the process plasma is turned off and the process gas is pumped out. The non-process gas is flowed into the chamber and the pressure is stabilized at a desired level before the RF power is turned on at a low level to strike a dechucking plasma. As an example, the RF power for the dechucking plasma is about 100-250 W, and the pressure in the chamber 102 is about 40-200 mT.

Shortly after the transition 210 is made, the Helium cooling gas is turned off and a process of evacuating the residual Helium from the cooling gas distribution system is begun (Step 230). As this is taking place, the chuck electrode 132 is brought to a dechucking electric potential, which is significantly different from the electric potential of the chuck electrode during the processing steps (Step 240). Typically, the dechucking electric potential is within the range from a few tens of volts below to a few tens of volts above the ground potential, depending on different configurations of the chuck 130 and the reactor 100. In one embodiment of the present invention, the dechucking electric potential is slightly more positive than (or a few volts above) the ground potential. After a delay period has elapsed during step 240, the plasma is turned off and the lift pins are used to raise the wafer from the E-chuck (Step 250). The delay period is required to allow charges on the wafer and the chuck electrode to bleed away while the dechucking plasma is still running. The time for running the dechucking plasma is typically several seconds.

In an alternative embodiment, step 250 is performed in several sub-steps. After the delay period, the lift pins are raised slightly (e.g. by a distance of about 10 to 60 mils) before turning off the dechucking plasma. The separation step is performed gently, typically taking several seconds to complete. During the separation operation, the dechucking plasma provides a path for further discharging of the wafer. Once the wafer is separated from the e-chuck, the source RF 126 is turned off, the non-process gas is turned off, and the lift pins are used to further raise the wafer to about 0.5 inch above the e-chuck. At this point, the wafer is dechucked and can be removed from the chamber.

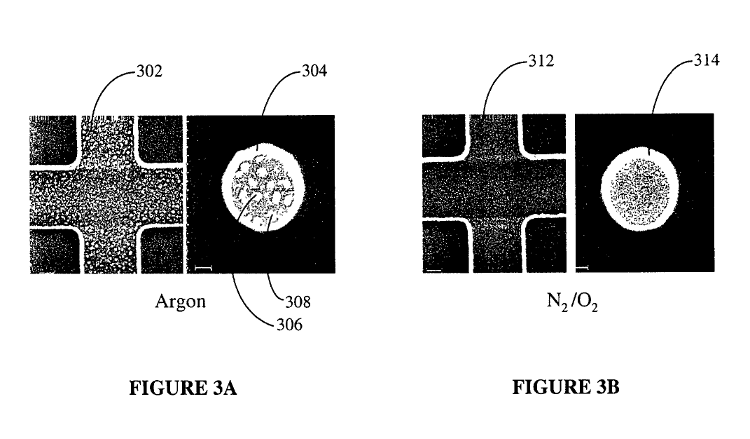

The N₂/O₂ plasma in the dechucking process 200 is found to be effective in softening metallic polymers such as TiN as well as other kinds of polymers from the processed feature surfaces of the wafer. The softened polymers are much easier to remove with post-etch cleaning processes such as photoresist ashing and conventional solvent clean. FIG. 3A and FIG. 3B are scanning electron micrographs (SEM) taken from two wafers that have gone through the same processing steps but different dechucking procedures. FIG. 3A shows in top-down view a cross-shaped area 302 and a hole 304 etched on a wafer that was dechucked with an Argon plasma, and FIG. 3B shows in top-down view a cross-shaped area 312 and a hole 314 on the other wafer that was dechucked with a N₂/O₂ plasma. Both wafers were wet cleaned using the same solvent that has just reached its lifetime specification. FIG. 3A shows that using the argon dechucking plasma has resulted in polymer residues, such as the ones shown by bright spots 306 and 308, not being cleaned off by the post-etch cleaning process. In contrast, FIG. 3B shows that using the N₂/O₂ dechucking plasma has resulted in significant improvement in the completeness of polymer removal. Therefore, with the N₂/O₂ plasma for dechucking, the lifetime of the solvent can be greatly extended.

The dechucking method 200 can be used after any plasma process involving an e-chuck. The exact order of some of the steps in the method 200 and/or the operation of the reactor 100 as described above can be altered. In addition, steps may be added or omitted and process parameters varied depending upon the requirements of a particular processing application and the particular plasma system in which the plasma processing takes place. The above operations and the order in which they are presented are chosen for illustrative purposes and to provide a picture of a complete run sequence.

What is claimed is:

1. A method for separating a wafer from an electrostatic chuck after plasma processing of the wafer, the electrostatic chuck having a chuck electrode, the method comprising:
providing a flow of a gas into the chamber, the gas including nitrogen and oxygen;
striking a plasma of the gas in the chamber; and
changing the electric potential of the chuck electrode to a dechucking electric potential before turning off the plasma.

2. The method of claim 1 wherein the dechucking potential is significantly different from the electric potential of the chuck electrode during the plasma processing of the wafer.

3. The method of claim 2 wherein the electric potential of the chuck electrode during the plasma processing of the wafer is in a range of a few hundred to a few thousand volts above or below ground potential.

4. The method of claim 3 wherein the electric potential of the chuck electrode during the plasma processing of the wafer is about 300 to about 800 above the ground potential.

5. The method of claim 1 wherein the dechucking potential is within the range of a few tens of volts above the ground potential to a few tens of volts below the ground potential.

6. The method of claim 5 wherein the dechucking potential is slightly more positive than the ground potential.

7. The method of claim 5 wherein the dechucking potential is about the same as the ground potential.

8. The method of claim 1 wherein the volumetric flow ratio of nitrogen:oxygen gas is about 1:1.

9. The method of claim 1 wherein the volumetric flow rate of nitrogen is about 5 sccm to about 300 sccm.

10. The method of claim 1 wherein the volumetric flow rate of oxygen is about 5 sccm to about 300 sccm.

11. The method of claim 1 wherein the plasma is maintained by coupling RF power into the chamber.

12. The method of claim 11 wherein the RF power is capacitively coupled into the chamber.

13. The method of claim 12 wherein the capacitively coupled RF power is about 100 to about 250 W.

14. The method of claim 1 wherein the gas pressure in the chamber when the plasma is running is about 40 to 200 mT.

15. The method of claim 1 wherein the chuck electrode is kept at the dechucking potential for a period of time before the plasma is turned off.

16. The method of claim 1 wherein the wafer is slightly separated from the electrostatic chuck before the plasma is turned off.
